(19) United States
(12) Patent Application Publication
(10) Pub. No.: US 2005/0145929 A1
(43) Pub. Date: Jul. 7, 2005

(54) Method and structure for layout of cell contact area for semiconductor integrated circuits

(75) Inventors: Chia-Te Wu, Shanghai (CN); Jian-Xiang Cai, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 10/773,961

(22) Filed: Feb. 6, 2004

(30) Foreign Application Priority Data
Dec. 30, 2003 (CN) 200310122971.5

(51) Int. Cl. H01L 29/792

(52) U.S. Cl. 257/326

(57) ABSTRACT

An EEPROM integrated circuit structure. The structure has a substrate that includes a surface region. Preferably, the surface region is provided within a first cell region. The structure also has a gate dielectric layer of first thickness overlying the surface of the substrate region and a select gate overlying a first portion of the gate dielectric layer. A floating gate is overlying a second portion of the gate dielectric layer and is coupled to the select gate. An insulating layer is overlying the floating gate. A control gate is overlying the insulating layer and is coupled to the floating gate. A tunnel window provided in a stripe configuration is formed within a portion of the gate dielectric layer. The portion of the gate dielectric layer is characterized by a second thickness, which is less than the first thickness.

### BACKGROUND OF THE INVENTION

The present invention is directed to integrated circuits and their processing for the manufacture of semiconductor devices. More particularly, the invention provides a method and resulting device for manufacturing a window structure for a tunnel dielectric in an EEPROM device using FLOTOX technology. But it would be recognized that the invention has a much broader range of applicability.

A variety of memory devices have been proposed or used in industry. An example of such a memory device is an erasable programmable read only memory (“EPROM”) device. The EPROM device is both readable and erasable, i.e., programmable. In particular, an EPROM is implemented using a floating gate field effect transistor, which has binary states. That is, a binary state is represented by the presence of absence of charge on the floating gate. The charge is generally sufficient to prevent conduction even when a normal high signal is applied to the gate of the EPROM transistor.

Numerous varieties of EPROMs are available. In the traditional and most basic form, EPROMs are programmed electrically and erased by exposure to ultraviolet light. These EPROMs are commonly referred to as ultraviolet erasable programmable read only memories (“UVEPROM”s). UVEPROMs can be programmed by running a high current between a drain and a source of the UVEPROM transistor while applying a positive potential to the gate. The positive potential on the gate attracts energetic (i.e., hot) electrons from the drain to source current, where the electrons jump or inject into the floating gate and become trapped on the floating gate.

Another form of EPROM is the electrically erasable programmable read only memory (“EEPROM” or “E² PROM”). EEPROMs are often programmed and erased electrically by way of a phenomenon known as Fowler Nordheim tunneling. Still another form of EPROM is a “Flash EPROM,” which is programmed using hot electrons and erased using the Fowler Nordheim tunneling phenomenon. Flash EPROMs can be erased in a “flash” or bulk mode in which all cells in an array or a portion of an array can be erased simultaneously using Fowler Nordheim tunneling, and are commonly called “Flash cells” or “Flash devices.”

A limitation with the flash memory cell is processing techniques have been limited to further reduce cell size and increase device density. As merely an example, such memory cell often includes a specific size for a tunnel oxide window, which is used for conventional FLOTOX based EEPROM technologies. That is, the tunnel oxide window often cannot be reduced in size to less than 0.4 um, which limits the ability of further increasing device density. These and other limitations have been described in more detail throughout the present specification and more particularly below.

From the above it is seen that a memory cell structure that is easy to fabricate, cost effective, and dense is often desired.

### BRIEF SUMMARY OF THE INVENTION

According to the present invention, techniques for processing integrated circuits for the manufacture of semiconductor devices are provided. More particularly, the invention provides a method and resulting device for manufacturing a window structure for a tunnel dielectric in an EEPROM device using FLOTOX technology. But it would be recognized that the invention has a much broader range of applicability.

In a specific embodiment, the invention provides a method for forming an EEPROM integrated circuit structure. The method includes providing a substrate including a surface region, which is provided within a first cell region. The method includes forming a gate dielectric layer of first thickness overlying the surface of the substrate region. The method also includes patterning the gate dielectric layer to form a plurality of stripes. Each of the stripes is characterized by a second thickness, which is less than the first thickness. Each of the stripes has a predetermined width and a predetermined length that have been formed using a phase shift mask. At least one of the stripes includes a stripe portion traversing through a portion of the first cell region and other cell regions, which may have other devices. The method also includes forming a floating gate overlying a portion of the gate dielectric layer. The portion of the gate dielectric layer includes the strip portion traversing through the portion of the gate dielectric layer. The method includes forming an insulating layer overlying the floating gate and forming a control gate overlying the floating gate overlying the insulating layer and coupled to the floating gate. Preferably, the stripe portion traverses through the portion of the first cell region includes a tunnel window for a memory device.

In an alternative embodiment, the invention provides an EEPROM integrated circuit structure. The structure has a substrate that includes a surface region. Preferably, the surface region is provided within a first cell region. The structure also has a gate dielectric layer of first thickness overlying the surface of the substrate region and a select gate overlying a first portion of the gate dielectric layer. A floating gate is overlying a second portion of the gate dielectric layer and is coupled to the select gate. An insulating layer is overlying the floating gate. A control gate is overlying the insulating layer and is coupled to the floating gate. A tunnel window provided in a stripe configuration is formed within a portion of the gate dielectric layer. The portion of the gate dielectric layer is characterized by a second thickness, which is less than the first thickness.

Many benefits are achieved by way of the present invention over conventional techniques. For example, the present technique provides an easy to use process that relies upon conventional technology. In some embodiments, the method provides higher device yields in dies per wafer and improved device density. Additionally, the method provides a process that is compatible with conventional process technology without substantial modifications to conventional equipment and processes. Preferably, the invention provides for an improved tunnel oxide window, which leads to higher device densities. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1 through 3 illustrate a method for forming a tunnel oxide window for a conventional EEPROM device; and

FIGS. 4 through 8 illustrate a method for forming an EEPROM device according to an embodiment of the present invention

### DETAILED DESCRIPTION OF THE INVENTION

According to the present invention, techniques for processing integrated circuits for the manufacture of semiconductor devices are provided. More particularly, the invention provides a method and resulting device for manufacturing a window structure for a tunnel dielectric in an EEPROM device using FLOTOX technology. But it would be recognized that the invention has a much broader range of applicability.

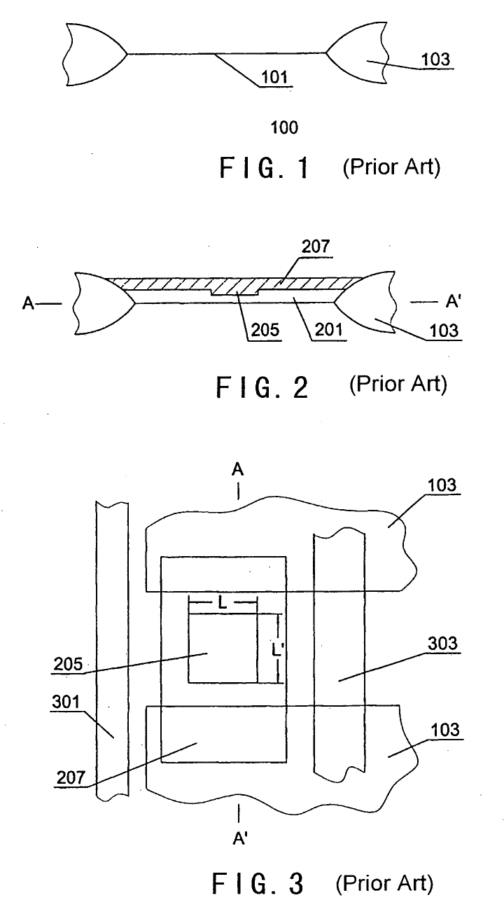

FIGS. 1 through 3 illustrate a method for forming a tunnel oxide window for a conventional EEPROM device. As shown, the conventional method begins by providing a substrate 101, which includes a surface region 101. The surface region is provided between isolation regions 103. The isolation regions are often formed using local oxidation of silicon, commonly called LOCOS. The method forms a dielectric layer 201 overlying the surface region. The dielectric layer is often patterned to form a tunnel window 205. The tunnel window is a region that has a thickness that is thinner than surrounding dielectric layer regions. A gate electrode layer 207 is often formed overlying the dielectric layer. Preferably, the gate electrode is a floating gate for EEPROM devices. Referring to FIG. 3, tunnel window 205 has a square confirmation, which is often formed using masking and etching techniques. Also shown is select gate 303 and source line 301 the floating gate 207 is formed overlying the dielectric layer, which is formed overlying the surface region. Field isolation oxide layers 103 are also shown. Certain limitations exist with this conventional EEPROM device. A width L′ and length L of the tunnel window can be provided only up to a certain dimension. That is, conventional tunnel windows can be 0.45 to about 0.8 microns in size, but often cannot be smaller using conventional masking and etching techniques. These and other limitations of conventional EEPROM devices can be found throughout the present specification. Further details of overcoming certain limitations of these conventional EEPROM devices are found throughout the present specification and more particularly below.

A method for fabricating an EEPROM device according to an embodiment of the present invention may be outlined as follows:
1. Provide a substrate including a surface region;
2. Form a gate dielectric layer of first thickness overlying the surface of the substrate region;
3. Pattern the gate dielectric layer using a phase shift mask to form a plurality of stripes, each of the stripes being characterized by a second thickness that is less than the first thickness;
4. Form a floating gate overlying a portion of the gate dielectric layer that includes a portion of at least one of the stripes;
5 Form an insulating layer overlying the floating gate;
6. Form a control gate overlying the floating gate overlying the insulating layer and coupled to the floating gate; and
7. Perform other steps, as desired.

The above sequence of steps provides a method according to an embodiment of the present invention. As shown, the method uses a combination of steps including a way of forming a tunnel dielectric window for an EEPROM device. Other alternatives can also be provided where steps are added, one or more steps are removed, or one or more steps are provided in a different sequence without departing from the scope of the claims herein. Further details of the present method can be found throughout the present specification and more particularly below.

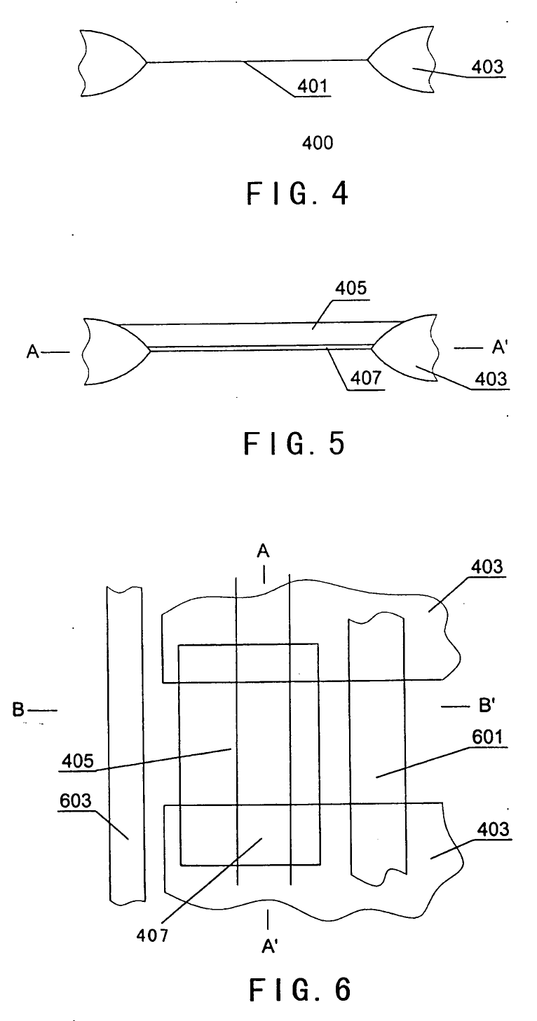

FIGS. 4 through 8 illustrate a method for forming an EEPROM device according to an embodiment of the present invention. These diagrams are merely examples, which should not unduly limit the scope of the claims herein. One of ordinary skill in the art would recognize many variations, alternatives, and modifications. In a specific embodiment, the invention provides a method for forming an EEPROM integrated circuit structure. As shown, the method begins by providing a substrate 401 including a surface region 400, which is provided within a first cell region. Other cell regions numbered from 2 through N (not shown) are also included. The substrate is a made of suitable material such as silicon, silicon on insulator, or epitaxial silicon. The surface region is provided between field isolation oxide regions 403. The field isolation oxide regions can be formed using any suitable techniques such as Local Oxidation of Silicon, commonly called LOCOS, or Shallow Trench Isolation, often called STI. Other isolation techniques can also be used.

The method also includes forming a gate dielectric layer of first thickness overlying the surface of the substrate region. The gate dielectric layer is often a high quality thermal oxide, silicon oxynitride, or silicon nitride, depending upon the application. The method also includes patterning the gate dielectric layer to form a plurality of stripes. Each of the stripes is characterized by a second thickness, which is less than the first thickness. Each of the stripes has a predetermined width and a predetermined length that have been formed using a phase shift mask. Preferably, the pre determined width is less than 0.25 microns, which leads to a smaller cell size. At least one 407 of the stripes includes a stripe portion traversing through a portion of the first cell region and other cell regions, which may have other devices. Referring to FIG. 6 (see reference letter A′ to A, which maps onto the same for FIG. 5), which is a top view diagram of an expanded view of FIG. 5, the device has a select gate 601, which runs along the cell. Field isolation oxide regions 403 are also shown. The stripe portion 407 is also shown. The stripe portion runs through the cell, as well as other cells, which are adjacent to the cell shown. The method also includes forming a floating gate 405 overlying a portion of the gate dielectric layer. As shown, as portion of the gate dielectric layer includes the stripe portion traversing through the portion of the gate dielectric layer.

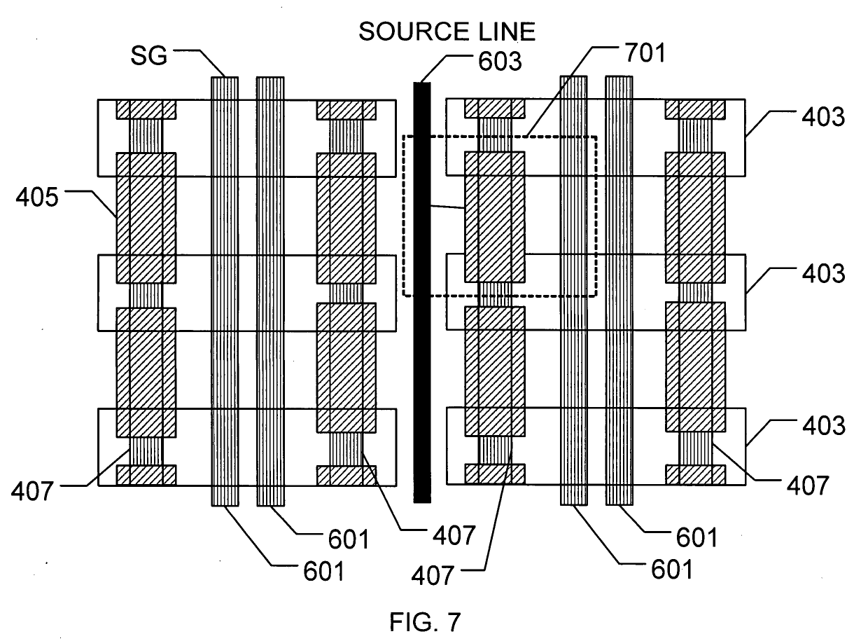

Referring now to FIG. 7, which illustrates a more expanded view of FIG. 6, a plurality of cells 701 are shown. Like reference numbers are used in this figure as certain other figures for illustrative purposes only. Such numbers are not intended to be limiting in any manner. As shown, each of the cells includes an EEPROM device. Each device has a select gate 601, which runs along the cell and other cells. Field isolation oxide regions 403 are also shown. The stripe portion 407 is also shown. The stripe portion runs through the cell, as well as other cells, which are adjacent to each other. A floating gate 405 overlying a portion of the gate dielectric layer is also shown. The floating gate is specific for each cell, as shown.

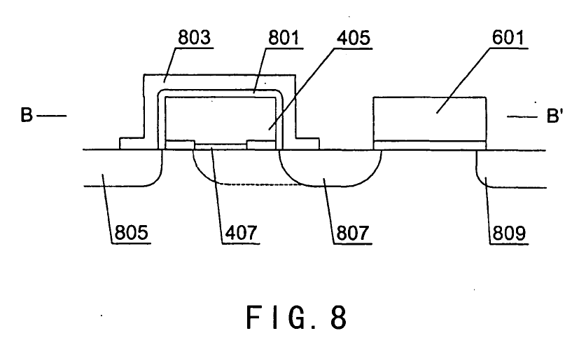

Referring to FIG. 8 (which takes a cross section along reference letters B to B′), the method includes forming an insulating layer 801 overlying the floating gate 405 and forming a control gate 803 overlying the floating gate. Preferably, the insulating layer is an oxide on nitride on oxide structure, commonly called ONO. As shown, the control gate is overlying the insulating layer and is coupled to the floating gate. As shown, the device also includes the stripe portion 407. Preferably, the stripe portion traverses through the portion of the first cell region includes a tunnel window for a memory device. The tunnel window has the second predetermined thickness, which can range from 40 to 80 Angstroms on certain embodiments. Other predetermined thicknesses can also be used. The device also includes diffusion region 807, which couples the select gate to the floating gate. The device also has source region 805 and drain region 809. This diagram is provided for illustration only and should not unduly limit the scope of the claims here.

It is also understood that the examples and embodiments described herein are for illustrative purposes only and that various modifications or changes in light thereof will be suggested to persons skilled in the art and are to be included within the spirit and purview of this application and scope of the appended claims.

1. An EEPROM integrated circuit structure, the structure comprising:
a substrate including a surface region, the surface region being provided within a first cell region;
a gate dielectric layer of first thickness overlying the surface region of the substrate;
a select gate overlying a first portion of the gate dielectric layer;
a floating gate overlying a second portion of the gate dielectric layer and coupled to the select gate;
an insulating layer overlying the floating gate;
a control gate overlying the insulating layer and coupled to the floating gate; and
a tunnel window provided in a stripe configuration, the stripe configuration is disposed within a portion of the gate dielectric layer, the portion of the gate dielectric layer being of a second thickness, the second thickness being less than the first thickness,
wherein the stripe configuration extending across an entire length of the first cell region from a first field isolation oxide region to a second field isolation oxide region.

2. The structure of claim 1 wherein the gate dielectric layer comprises a silicon dioxide.

3. The structure of claim 1 wherein the tunnel window is characterized by a width of less than 0.25 microns.

4. The structure of claim 1 wherein the insulating layer is an ONO layer coupled between the floating gate and the control gate.

5. The structure of claim 1 wherein the floating gate has a width of 1.5 microns.

6. The structure of claim 1 wherein the tunnel window is provided using a phase shift mask.

7. The structure of claim 1 wherein the stripe configuration extends through a plurality of cells, each of the cells being separated by a field oxide region.

8. The structure of claim 1 wherein the substrate is a semiconductor wafer.

9. The structure of claim 1 wherein the select gate, floating gate, and control gate are provided within the first cell region, the first cell region being provided within an isolation region.

10. The structure of claim 1 wherein the stripe configuration runs through the first cell region to other cell regions numbered from 2 through N, where N is an integer greater than 2.

11. A method for manufacturing an EEPROM integrated circuit structure, the method comprising:
providing a substrate including a surface region, the surface region being provided within a first cell region;
forming a gate dielectric layer of a first thickness overlying the surface region of the substrate;
patterning the gate dielectric layer to form a plurality of stripes, each of the plurality of stripes being characterized by a second thickness, the second thickness being less than the first thickness, each of the plurality of stripes having a predetermined width and a predetermined length, at least one of the plurality of stripes includes a stripe portion traversing through a portion of the first cell region and other cell regions;
forming a floating gate overlying a portion of the gate dielectric layer, the portion of the gate dielectric layer including the stripe portion traversing through the portion of the gate dielectric layer;
forming an insulating layer overlying the floating gate; and
forming a control gate overlying the insulating layer and coupled to the floating gate,
wherein the stripe portion traversing across an entire length of the first cell region from a first field isolation oxide region to a second field isolation oxide region, the stripe portion includes a tunnel window for a memory device.

12. The method of claim 11 wherein the gate dielectric layer comprises a silicon dioxide.

13. The method of claim 11 wherein the tunnel window is characterized by a width of less than 0.25 microns.

14. The method of claim 11 wherein the insulating layer is an ONO layer coupled between the floating gate and the control gate.

15. The method of claim 11 wherein the floating gate has a width of 1.5 microns.

16. The method of claim 11 wherein the tunnel window is provided using a phase shift mask.

17. The method of claim 11 wherein the at least one of the plurality of stripes extends through a plurality of cells, each of the cells being separated by a field oxide region.

18. The method of claim 11 wherein the substrate is a semiconductor wafer.

19. The method of claim 11 wherein the floating gate and the control gate are provided within the first cell region, the first cell region being provided within an isolation region.

20. The method of claim 11 wherein at least one of the plurality of stripes runs through the first cell region to the other cell regions, the other cell regions being numbered from 2 through N, where N is an integer greater than 2.
